(19) United States
(12) Patent Application Publication
(10) Pub. No.: US 2023/0300536 A1
(43) Pub. Date: Sep. 21, 2023

(54) VIBRATION SENSOR AND MICROPHONE

(71) Applicant: Shenzhen Shokz Co., Ltd., Shenzhen (CN)

(72) Inventors: Wenjun DENG, Shenzhen (CN); Wenbing ZHOU, Shenzhen (CN); Yongshuai YUAN, Shenzhen (CN)

(73) Assignee: Shenzhen Shokz Co., Ltd., Shenzhen (CN)

(21) Appl. No.: 18/200,798

(22) Filed: May 23, 2023

Related U.S. Application Data
(63) Continuation of application No. PCT/CN2021/081083, filed on Mar. 16, 2021.

(51) Int. Cl. H04R 17/02; H04R 19/04; H04R 7/20; H10N 30/30; H10N 30/50

(52) U.S. Cl. CPC H04R 17/025; H04R 7/20; H04R 19/04; H10N 30/308; H10N 30/50; H10N 30/872

(57) ABSTRACT

A vibration sensor and a microphone are provided. The vibration sensor includes a piezoelectric system and a capacitive system. The piezoelectric system includes a vibration component and a piezoelectric sensing component collecting a first electrical signal generated due to deformation of the vibration component. The capacitive system uses the vibration component in the piezoelectric system as a movable capacitive plate and a fixed substrate opposite to the vibration component to form a capacitive vibration sensor. The deformation of the vibration component changes a distance between the vibration component and the fixed substrate. A capacitive sensing component collects a second electrical signal generated due to the distance change. The capacitive sensing component is disposed in a region where the first electrical signal in the piezoelectric system is low, thereby better using space of the vibration sensor, and enhancing the second electrical signal without affecting output of the first electrical signal.

### RELATED APPLICATIONS

This application is a continuation application of PCT application No. PCT/CN2021/081083, filed on Mar. 16, 2021, and the contents of which are incorporated herein by reference in their entirety.

### TECHNICAL FIELD

This disclosure relates to the field of audio collection technologies, and in particular to a vibration sensor and a microphone.

### BACKGROUND

Currently, a microphone usually uses a vibration sensor to receive an external vibration signal, and converts the vibration signal into an electrical signal, processes the electrical signal by a back-end circuit then outputs an electrical signal, thereby realizing a collection of a sound signal. An air-conduction microphone may collect an air vibration signal generated when a user makes a sound, and convert the air vibration signal into an electrical signal. A bone-conduction microphone may collect mechanical vibration signals of bones and skin generated when a user speaks, and convert the mechanical vibration signals into electrical signals. In an existing piezoelectric vibration sensor, a strain at an edge junction of a piezoelectric layer is relatively large, a piezoelectric effect is significant, and an output voltage of a valid electrical signal is relatively high, while a strain in a central region is relatively small, and an output voltage of a valid electrical signal is relatively low. Particularly, for a piezoelectric vibration sensor connected with a counterweight, an output voltage of a valid electrical signal in a region where the counterweight is mounted is relatively low. The above phenomenon causes relatively low sensitivity of a microphone and waste of space.

Therefore, there is a need to provide a vibration sensor and a microphone that have high sensitivity and high space utilization.

### BRIEF SUMMARY

This disclosure provides a vibration sensor and a microphone that have high sensitivity and high space utilization.

According to a first aspect, this disclosure provides a vibration sensor, including: a base; a vibration component, connected to the base and configured to generate a target displacement and a target deformation in response to a vibration of the base; a piezoelectric sensing component, connected to the vibration component and configured to convert the target deformation to a first electrical signal; a fixed substrate, disposed opposite to the vibration component with an interval; and a capacitive sensing component, connected to the fixed substrate and the vibration component, and configured to convert a distance change between the fixed substrate and the vibration component caused by the target displacement to a second electrical signal.

According to a second aspect, this disclosure provides a microphone, including: a housing; a vibration sensor mounted in the housing, where the vibration sensor includes: a base, a vibration component, connected to the base and configured to generate a target displacement and a target deformation in response to a vibration of the base, a piezoelectric sensing component, connected to the vibration component and configured to convert the target deformation to a first electrical signal, a fixed substrate, disposed opposite to the vibration component with an interval, and a capacitive sensing component, connected to the fixed substrate and the vibration component, and configured to convert a distance change between the fixed substrate and the vibration component caused by the target displacement to a second electrical signal, where the base is fixedly connected to the housing; and a signal synthesizing circuit, connected to the piezoelectric sensing component and the capacitive sensing component, and configured to synthesize a third electrical signal based on the first electrical signal and the second electrical signal, where a signal strength of the third electrical signal is greater than a signal strength of the first electrical signal and a signal strength of the second electrical signal.

It can be learned from the above technical solutions that a vibration sensor and a microphone provided in this disclosure are composed of a piezoelectric system and a capacitive system. The piezoelectric system may include a vibration component and a piezoelectric sensing component that is configured to collect an electrical signal. The vibration component may include an elastic layer and a counterweight connected to the elastic layer. The elastic layer may generate deformation in response to an excitation of the vibration of the base. The counterweight may generate displacement based on the deformation. The piezoelectric sensing component may collect a first electrical signal generated due to deformation of the vibration component. The capacitive system may be directly connected to the piezoelectric system, and may include a fixed substrate and a capacitive sensing component that may collect an electrical signal. The capacitive system may use the vibration component in the piezoelectric system as a movable capacitive plate in the capacitive system. On this basis, a fixed substrate may be additionally disposed opposite to the movable capacitive plate composed of the vibration component, to form a capacitive vibration sensor. A distance between the vibration component and the fixed substrate may change due to the displacement of the counterweight in the vibration component. A capacitive sensing component may collect a second electrical signal generated due to the distance change in the capacitive system. The piezoelectric sensing component may be disposed in a region that is in the piezoelectric system and that has high output strength of the first electrical signal, for example, a region at the periphery of the counterweight and a region connected to the elastic layer and the base. The capacitive sensing component may be disposed in a region that is in the piezoelectric system and that has low output strength of the first electrical signal, for example, a region corresponding to the counterweight. The piezoelectric sensing component and the capacitive sensing component may be distributed in different regions, to use space of the vibration sensor rationally. The capacitive system may be additionally disposed without affecting output strength of the first electrical signal of the piezoelectric system, to increase the second electrical signal collected by the capacitive system. Therefore, entire electrical signal output strength of the vibration sensor is improved; space utilization is increased while sensitivity of the vibration sensor is improved; and a device size is decreased.

Other functions of the vibration sensor and the microphone provided in this disclosure are listed in the following descriptions. Based on descriptions, content introduced by the following figures and examples are obvious to those of ordinary skill in the art. Creative aspects of the vibration sensor and the microphone provided in this disclosure may be fully explained by practicing or using a method, an apparatus, and a combination described in the following detailed examples.

### BRIEF DESCRIPTION OF THE DRAWINGS

To describe the technical solutions in the embodiments of this disclosure, the following briefly describes the accompanying drawings required for describing the embodiments. Apparently, the accompanying drawings in the following description show merely some exemplary embodiments of this disclosure, and a person of ordinary skill in the art may still derive other drawings from these accompanying drawings without creative efforts.

FIG. 1 is a sectional view of a vibration sensor according to some exemplary embodiments of this disclosure;

FIG. 2 is a sectional view in direction A-A in FIG. 1;

FIG. 3 is a sectional view of a vibration sensor according to some exemplary embodiments of this disclosure;

FIG. 4 is a sectional view of a vibration sensor according to some exemplary embodiments of this disclosure;

FIG. 5 is a sectional view of a vibration sensor according to some exemplary embodiments of this disclosure; and

FIG. 6 is a flowchart of a method for manufacturing a vibration sensor according to some exemplary embodiments of this disclosure.

### DETAILED DESCRIPTION

The following description provides specific application scenarios and requirements of this disclosure, with the purpose of enabling those skilled in the art to make and use the content in this disclosure. For those skilled in the art, various partial modifications to the disclosed embodiments are obvious, and without departing from the spirit and scope of this disclosure, the general principles defined herein can be applied to other embodiments and application. Therefore, this disclosure is not limited to the embodiments, but is consistent with the widest scope of the claims.

The terms used herein are merely intended to describe specific exemplary embodiments, rather than to limit this disclosure. For example, unless explicitly stated otherwise, the singular forms “a”, “an” and “this” used herein may also include plural forms. When used in this disclosure, the terms “comprise”, “include”, and/or “contain” indicate the presence of associated integers, steps, operations, elements, and/or components, but do not exclude the presence of one or more other features, integers, steps, operations, elements, components, and/or sets or addition of other features, integers, steps, operations, elements, components, and/or sets to the system/method.

In consideration of the following description, these features in this disclosure and other features, the operation and function of related elements of the structure, as well as the economics of the combination and manufacturing of components can be significantly improved. With reference to the accompanying drawings, all of these form part of this disclosure. However, it should be understood that the accompanying drawings are merely intended for illustration and description purposes, rather than to limit the scope of this disclosure. It should be further understood that the accompanying drawings are not drawn to scale.

It should be understood that, to facilitate description of this disclosure, position relationships indicated by terms such as “center”, “upper surface”, “lower surface”, “upper”, “lower”, “top”, “bottom”, “inner”, “outer”, “axial”, “radial”, “periphery”, and “external” are positional relationships based on the accompanying drawings, and are not intended to indicate that the apparatus, module, or unit referred to must have a particular positional relationship, therefore they cannot be interpreted as limiting this disclosure.

It should be understood that “system”, “apparatus”, “unit”, and/or “module” used in this disclosure are used to distinguish different modules, elements, components, parts, or assemblies of different levels. However, if any other word can achieve the same purpose, it can be replaced with other expressions.

The flowchart used in this disclosure illustrates the operations implemented by the system according to some exemplary embodiments in this disclosure. It should be clearly understood that the operations of the flowchart may be implemented out of sequence. Instead, the operations may be implemented in reverse sequence or simultaneously. In addition, one or more other operations may be added to the flowchart. One or more operations may be removed from the flowchart.

A vibration sensor and a microphone provided in this disclosure may be used to collect an external vibration signal, and convert the vibration signal into an electrical signal. The vibration sensor and the microphone may be used to collect not only an air vibration signal, but also a mechanical vibration signal, such as vibration of bones and skin generated when a person speaks. The vibration sensor and the microphone may be used as not only an air-conduction microphone, but also a bone-conduction microphone.

According to the vibration sensor and the microphone provided in this disclosure, a capacitive system may be additionally provided in a piezoelectric system, to effectively utilize a region with relatively low valid electrical signal output in the piezoelectric system as an electrical signal output region of the capacitive system, thereby better utilizing space of the vibration sensor. In addition, electrical signals collected by the capacitive system may be increased without affecting electrical signal output strength of the piezoelectric system, so as to improve entire electrical signal output strength of the vibration sensor. In this way, space utilization is improved while sensitivity of the vibration sensor is also improved; and a device volume is decreased.

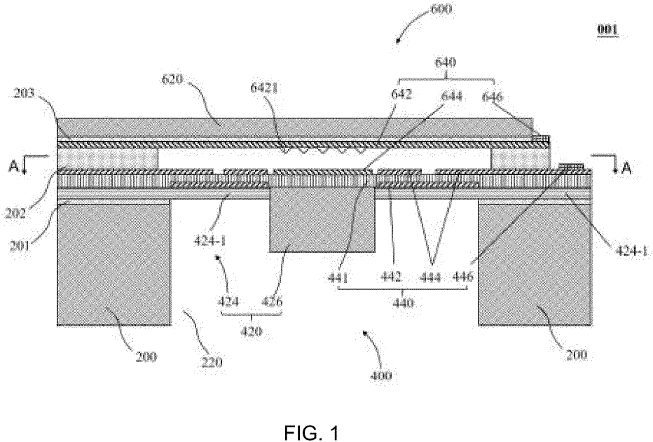

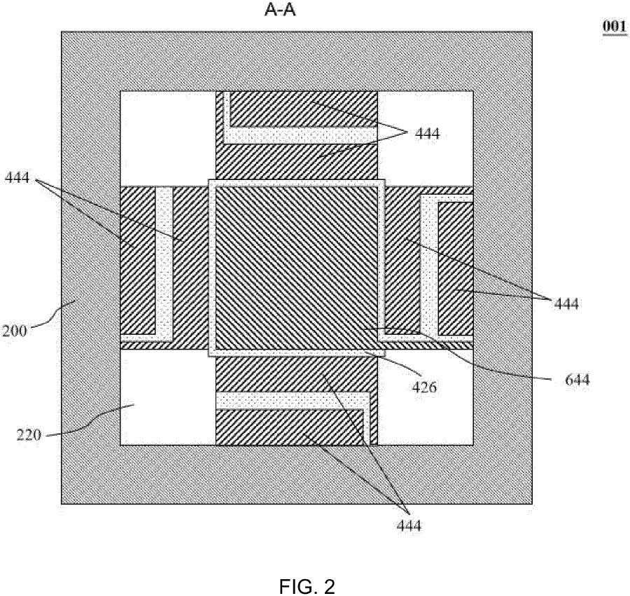

FIG. 1 is a sectional view of a vibration sensor 001 according to some exemplary embodiments of this disclosure. FIG. 2 is a sectional view in direction A-A in FIG. 1. As shown in FIG. 1 and FIG. 2, the vibration sensor 001 may include a base 200, a piezoelectric system 400, and a capacitive system 600.

The base 200 may be a mounting base for the vibration sensor 001. Other components, such as the piezoelectric system 400 and the capacitive system 600, of the vibration sensor 001 may be connected with the base 200 directly or indirectly. The connection may be implemented in any manner, for example, a fixed connection manner such as welding, riveting, clamping, or bolting, or a deposition manner such as physical deposition (for example, physical vapor deposition) or chemical deposition (for example, chemical vapor deposition). The piezoelectric system 400 may be disposed opposite to the capacitive system 600 with an interval.

The base 200 may be a structural body of any shape, for example, a regular-shaped structural body such as a cube, a cuboid, a cylinder, a prismoid, and a truncated cone, or an irregular-shaped structural body. In some exemplary embodiments, the base 200 may include a cavity 220 penetrating therethrough. As exemplarily illustrated in FIG. 1 and FIG. 2, the cavity 220 may penetrate an upper surface and a lower surface of the base 200. A section of the cavity 220 may be of any shape, for example, a regular shape such as a square, a rectangle, a circle, or a polygon, or an irregular shape.

The piezoelectric system 400 may be connected to the base 200. The connection may be direct or indirect connection. As described above, the vibration sensor 001 may receive an external vibration signal, and convert the external vibration signal into an electrical signal. For the piezoelectric system 400 of the vibration sensor 001, the external vibration signal may generate pressure on a piezoelectric material in the piezoelectric system 400, and enable the piezoelectric material to generate a voltage, thereby converting the external vibration signal into an electrical signal.

The piezoelectric system 400 may be connected to a side of the base 200. For example, at least a part of the structure of the piezoelectric system 400 may be fixed on the upper surface or the lower surface of the base 200. The piezoelectric system 400 may be alternatively connected to another portion of the base 200. For example, the piezoelectric system 400 may be alternatively connected to a side wall of the base 200. At least a portion of the structure of the piezoelectric system 400 may be fixed on an inner wall of the cavity 220 of the base 200. The piezoelectric system 400 may be disposed in the cavity 220. At least a portion of the piezoelectric system 400 may not be connected to the base 200. In other words, at least a portion of the piezoelectric system 400 may be suspended in the cavity 220. “Suspended in the cavity 220” may refers to being suspended in, below, or above the cavity 220 of the base 200, without contacting the base 200. For ease of illustration, as shown in FIG. 1, the piezoelectric system 400 may be connected to the upper surface of the base 200, which is merely an exemplary description.

As shown in FIG. 1 and FIG. 2, the piezoelectric system 400 may include a vibration component 420 and a piezoelectric sensing component 440. The piezoelectric system 400 may be a stacked structure composed of the vibration component 420 and the piezoelectric sensing component 440.

The vibration component 420 may be connected to the base 200, and configured to generate a target displacement and a target deformation in response to a vibration of the base 200. The connection may be implemented in any manner, for example, a fixed connection manner such as welding, riveting, clamping, or bolting, or a deposition manner such as physical deposition (for example, physical vapor deposition) or chemical deposition (for example, chemical vapor deposition). Specifically, the base 200 may generate a vibration based on the external vibration signal; the vibration component 420 may generate the target deformation in response to the vibration of the base 200; and the target displacement may be further generated based on the target deformation. It should be noted that the vibration component 420 may include the foregoing piezoelectric material. The piezoelectric material may be configured to generate a voltage under the pressure of the target deformation. The piezoelectric sensing component 440 may be connected to the vibration component 420, and configured to convert the target deformation of the vibration component 420 into a first electrical signal. Specifically, the piezoelectric sensing component 440 may be connected to the vibration component 420 to collect a voltage generated in the piezoelectric material, convert the voltage into the first electrical signal, and then output the first electrical signal. The vibration component 420 may be connected to the base 200 in an insulated manner. For example, the vibration component 420 may be connected to the base 200 via a first insulation layer 201. The vibration component 420 may be a portion that is easily deformed by an external force. At least part of the vibration component 420 may be suspended in the cavity 220. As shown in FIG. 1 and FIG. 2, the vibration component may include an elastic layer 424. In some exemplary embodiments, the vibration component 420 may further include a counterweight 426.

The elastic layer 424 may be fixedly connected with the base 200 directly or indirectly. The connection may be implemented in any manner, for example, a fixed connection manner such as welding, riveting, clamping, or bolting, or a deposition manner such as physical deposition (for example, physical vapor deposition) or chemical deposition (for example, chemical vapor deposition). When the base 200 receives an external vibration signal, the elastic layer 424 may generate the target deformation based on an excitation of the vibration of the base 200. The elastic layer 424 may be made of a material that can be easily deformed by an external force. The elastic layer 424 may be of a structure that can be easily deformed, and is made of a semiconductor material. In some exemplary embodiments, the semiconductor material may include silicon dioxide, silicon nitride, gallium nitride, zinc oxide, silicon carbide, and the like. The elastic layer 424 may include a fixed end and a free end. The fixed end may be fixedly connected with the base 200 directly or indirectly. The free end may be suspended in the cavity 220.

In some exemplary embodiments, the elastic layer 424 may be a supporting beam structure. As shown in FIG. 1 and FIG. 2, the elastic layer 424 may include a plurality of elastic supporting beams 424-1. One end of each elastic supporting beam 424-1 may be fixedly connected to the upper surface or the lower surface of the base 200 or the inner wall of the cavity 220. The other end of each elastic supporting beam 424-1 may be connected to the counterweight 426 and suspended in the cavity 220. In other words, two ends of each elastic supporting beam 424-1 may constitute the fixed end and the free end respectively. The elastic supporting beam 424-1 may be a plate-like structural body of any shape, for example, a rectangular beam, a trapezoidal beam, an L-shaped beam, a beam of another shape, or the like. The elastic layer 424 may include any quantity of elastic supporting beams 424-1. The elastic supporting beams 424-1 may be distributed around a center of the cavity 220 in a peripheral direction. For example, the quantity may be 2, 3, 4, 5, 6, 7, 8, or 10. As shown in FIG. 2, the elastic layer 424 may include four elastic supporting beams 424-1.

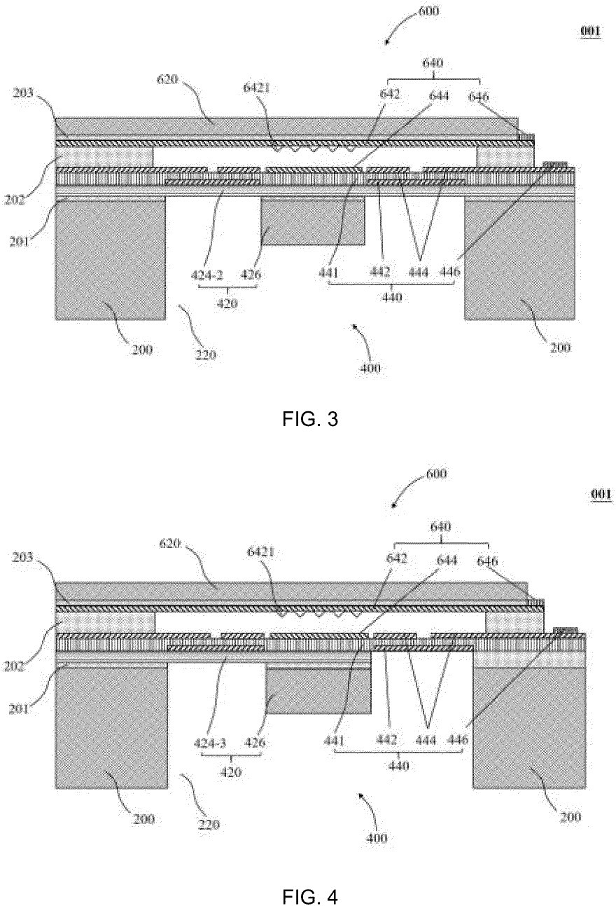

FIG. 3 is a sectional view of another vibration sensor 001 according to some exemplary embodiments of this disclosure. As shown in FIG. 3, the elastic layer 424 may alternatively be a suspended membrane structure 424-2. A periphery of the suspended membrane structure 424-2 may be connected to the base 200 and fixed on the base 200. a central region of the suspended membrane structure 424-2 may be connected to the counterweight 426 and be suspended on the cavity 220 of the base 200. In other words, the fixed end may include the periphery of the suspended membrane structure 424-2, and the free end may include the central region of the suspended membrane structure 424-2. In some exemplary embodiments, a shape of the suspended membrane structure 424-2 may be a circle, an oval, a triangle, a quadrangle, a polygon, or any other shape. In some exemplary embodiments, the suspended membrane structure 424-2 may include at least one hole. The at least one hole may be disposed at a position of the suspended membrane structure 424-2 close to the free end, and may be distributed around a center of the counterweight 426 in a peripheral direction of the counterweight 426. The at least one hole disposed on the suspended membrane structure 424-2 may adjust the rigidity of the suspended membrane structure 424-2 at different positions, thereby reducing the rigidity of the suspended membrane structure 424-2 in a region near the at least one hole, and relatively increasing the rigidity of the suspended membrane structure 424-2 away from the at least one hole. When the suspended membrane structure 424-2 moves relative to the base 200, a deformation degree in a region of the suspended membrane structure 424-2 near the at least one hole is relatively high, and a deformation degree in a region of the suspended membrane structure 424-2 away from the at least one hole is relatively low. In this case, disposing the piezoelectric sensing component 440 in a region of the suspended membrane structure 424-2 near the at least one hole may help the piezoelectric sensing component 440 collect vibration signals in a better way, thereby improving sensitivity of the vibration sensor 001. In addition, structures of all components in the vibration sensor 001 may be relatively simple, which facilitates production or assembly. In some exemplary embodiments, the at least one hole may be a hole of any shape, such as a circular hole, an oval hole, a square hole, or another polygonal hole. In some exemplary embodiments, resonant frequency, stress distribution, and the like of the vibration sensor 001 may also be adjusted by changing a size, quantity, spacing distance, and position of the at least one hole, thereby improving sensitivity of the vibration sensor 001.

In some exemplary embodiments, the vibration sensor 001 may also change the deformation stress of the suspended membrane structure at different positions by adjusting the thickness or density of the suspended membrane structure 424-2 in different regions. In some exemplary embodiments, the piezoelectric sensing component 440 may be set as a circular structure. The thickness of a region of the suspended membrane structure 424-2 on an inner side of the circular structure is greater than the thickness of a region of the suspended membrane structure 424-2 on an outer side of the circular structure. In some other embodiments, the density of the region of the suspended membrane structure 424-2 on the inner side of the circular structure is greater than the density of the region of the suspended membrane structure 424-2 on the outer side of the circular structure. In the vibration sensor 001, the density or thickness at different positions of the suspended membrane structure 424-2 may be changed to make the mass of a suspended membrane in the region on the inner side of the circular structure greater than the mass of a suspended membrane in the region on the outer side of the circular structure. When the suspended membrane structure 424-2 moves relative to the base 200, a deformation degree of a region of the suspended membrane structure 424-2 near the circular structure of the piezoelectric sensing component 440 is relatively high, and the deformation stress generated in the region is also relatively great, so that an electrical signal output by the vibration sensor 001 is increased.

FIG. 4 is a sectional view of another vibration sensor 001 according to some exemplary embodiments of this disclosure. As shown in FIG. 4, the elastic layer 424 may alternatively have a cantilever beam structure 424-3. The elastic layer 424 may include a cantilever beam 424-3. One end of the cantilever beam 424-3 may be fixedly connected to the upper surface or the lower surface of the base 200 or the inner wall of the cavity 220. The other end of the cantilever beam 424-3 may be suspended in the cavity 220. The other end of the cantilever beam 424-3 may be or may not be connected to the counterweight 426. In other words, two ends of the cantilever beam 424-3 may constitute the fixed end and the free end respectively. The cantilever beam 424-3 may be a plate-like structural body of any shape, for example, may be a rectangular beam, a trapezoidal beam, an L-shaped beam, a beam of another shape, or the like.

The elastic layer 424 may alternatively be any other structural form that may generate deformation based on an external vibration signal, which is not limited in this disclosure. For ease of illustration, in the following description, the elastic layer 424 is described as a supporting beam structure. Those skilled in the art should understand that the elastic layer 424 of other structures also falls within the scope of protection of this disclosure.

In some exemplary embodiments, the vibration component 420 may further include a counterweight 426. The counterweight 426 may be connected with the elastic layer 424 directly or indirectly. When the base 200 receives an external vibration signal, the elastic layer 424 may generate the target deformation based on an excitation of the vibration of the base 200; and the counterweight 426 may generate the target displacement based on the target deformation. The counterweight 426 may be fixedly connected to the free end of the elastic layer 424. In some exemplary embodiments, the counterweight 426 may protrude sideward relative to the elastic layer 424, and be suspended in the cavity 220. For example, the counterweight 426 may protrude upwards relative to the elastic layer 424, and be suspended in the cavity 220. The counterweight 426 may alternatively protrude downwards relative to the elastic layer 424, and be suspended in the cavity 220.

The counterweight 426 may allow the elastic layer 424 to easily deform by an external force, thereby increasing an output voltage of the first electrical signal of the piezoelectric sensing component 440. The counterweight 426 may be disposed in the center of the cavity 220. A sectional shape of the counterweight 426 may be a circle, a triangle, a quadrangle, a polygon, or the like. In some exemplary embodiments, the output voltage of the first electrical signal of the piezoelectric sensing component 440 may be increased by changing a size, a shape, or a position of the counterweight 426. Natural frequency and vibration amplitude of the vibration component 420 during vibration may be changed by adding the counterweight 426. In some exemplary embodiments, the first electrical signal may be increased by changing a size, a shape, or a position of the counterweight 426.

The piezoelectric sensing component 440 may include a piezoelectric layer 441. The piezoelectric layer 441 is a structure that may generate voltages on two end surfaces thereof by an external force. The piezoelectric layer 441 may be fixedly connected with the electrical base 200 directly or indirectly. The connection may be implemented in any manner, for example, a fixed connection manner such as welding, riveting, clamping, or bolting, or a deposition manner such as physical deposition (for example, physical vapor deposition) or chemical deposition (for example, chemical vapor deposition). In some exemplary embodiments, the piezoelectric layer 441 may generate the target deformation when receiving the vibration signal, and then generate a voltage based on the target deformation.

The piezoelectric layer 441 may be attached to a surface of the elastic layer 424 directly or indirectly. In some exemplary embodiments, the elastic layer 424 may be connected to the base 200 directly; and the piezoelectric layer 441 may be connected with the base 200 indirectly via the elastic layer 424. An example in which the vibration component 420 is disposed on the upper surface of the base 200 is used for description. In some exemplary embodiments, the piezoelectric layer 441 may be disposed on a side, away from the base 200, of the elastic layer 424; and the Istacked structure composed of the vibration component 420 and the piezoelectric sensing component 440 may include the piezoelectric layer 441, the elastic layer 424, and the counterweight 426 sequentially from top to bottom. In some exemplary embodiments, the piezoelectric layer 441 may be disposed on a side of the elastic layer 424 close to the base 200; and the stacked structure composed of the vibration component 420 and the piezoelectric sensing component 440 may include the counterweight 426, the elastic layer 424, and the piezoelectric layer 441 sequentially from top to bottom. As exemplarily illustrated in FIG. 1 and FIG. 2, the elastic layer 424 may be connected to the base 200 directly; and the piezoelectric layer 441 may be connected to the elastic layer 424, and be disposed on a side of the elastic layer 424 away from the base 200, that is, on top of the elastic layer 424. The counterweight 426 may be connected to the elastic layer 424, and be disposed below the elastic layer 424. When the base 200 receives an external vibration signal, the elastic layer 424 may generate the target deformation based on the vibration signal. Based on a piezoelectric effect, the piezoelectric layer 441 may be stressed by the target deformation of the elastic layer 424, thereby generating a voltage (a potential difference).

In some exemplary embodiments, the piezoelectric layer 441 may be a piezoelectric polymer thin film obtained according to a semiconductor deposition process (for example, magnetron sputtering or metal organic chemical vapor deposition (MOCVD)). In some exemplary embodiments, a material of the piezoelectric layer 441 may include a piezoelectric crystal material and a piezoelectric ceramics material. The piezoelectric crystal material may be piezoelectric mono-crystal. In some exemplary embodiments, the piezoelectric crystal material may include crystal, sphalerite, boracite, tourmaline, zincite, GaAs, barium titanate and derived crystal thereof, KH2PO4, NaKC4H4O6·4H2O (rochelle salt), or any combination thereof. The piezoelectric ceramics material may be piezoelectric poly-crystal formed through irregular collection of fine grains that are obtained after solid-phase reaction and sintering between powder particles of different materials. In some exemplary embodiments, the piezoelectric ceramics material may include barium titanate (BT), lead zirconate titanate (PZT), lithium lead barium niobate (PBLN), modified lead titanate (PT), aluminum nitride (AIN), zinc oxide (ZnO), or any combination thereof. In some exemplary embodiments, the material of the piezoelectric layer 441 may alternatively be a piezoelectric polymer material, for example, polyvinylidene fluoride (PVDF).

The piezoelectric sensing component 440 may further include a first piezoelectric electrode layer 442 and a second piezoelectric electrode layer 444. The first piezoelectric electrode layer 442 and the second piezoelectric electrode layer 444 may be respectively distributed on surfaces of two sides of the piezoelectric layer 441. The piezoelectric layer 441 may be disposed between the first piezoelectric electrode layer 442 and the second piezoelectric electrode layer 444. The piezoelectric layer 441 may deform along with the target deformation of the elastic layer 424 by an external vibration signal, and generate a voltage by the deformation stress. The first piezoelectric electrode layer 442 and the second piezoelectric electrode layer 444 may collect the voltage and generate the first electrical signal. The first piezoelectric electrode layer 442 is positionally aligned with the second piezoelectric electrode layer 444.

As described above, the piezoelectric layer 441 may be connected to the elastic layer 424, and distributed on a side of the elastic layer 424. In some exemplary embodiments, the first piezoelectric electrode layer 442 may be distributed between the piezoelectric layer 441 and the elastic layer 424; and the second piezoelectric electrode layer 444 may be distributed on a side of the piezoelectric layer 441 away from the elastic layer 424. In some other embodiments, the second piezoelectric electrode layer 444 may be distributed between the piezoelectric layer 441 and the elastic layer 424; and the first piezoelectric electrode layer 442 may be distributed on the side of the piezoelectric layer 441 away from the elastic layer 424.

In some exemplary embodiments, the first piezoelectric electrode layer 442 and the second piezoelectric electrode layer 444 may be structures of a conductive material. Exemplarily, the conductive material may include a metal, an alloy material, a metal oxide material, graphene, or the like, or any combination thereof. In some exemplary embodiments, the metal may include nickel, iron, lead, platinum, titanium, copper, molybdenum, zinc, or any combination thereof. In some exemplary embodiments, the alloy material may include a copper-zinc alloy, a copper-tin alloy, a copper-nickel-silicon alloy, a copper-chromium alloy, a copper-silver alloy, or any combination thereof. In some exemplary embodiments, the metal oxide material may include RuO₂, MnO₂, PbO₂, NiO, or the like, or any combination thereof.

When the vibration component 420 moves relative to the base 200, deformation degrees at different positions of the vibration component 420 may be different. In other words, different positions of the vibration component 420 exert different deformation stress on the piezoelectric layer 441. To improve sensitivity of the vibration sensor 001, in some exemplary embodiments, the piezoelectric sensing component 440 can be disposed at only a position(s) of the vibration component 420 where the vibration component 420 has a relatively high deformation degree, thereby improving the sensitivity of the vibration sensor 001. For ease of description, the position of the vibration component 420 having the relatively high deformation degree is defined as a first region; and a position of the vibration component 420 having a relatively low deformation degree is defined as a second region. A voltage of the first electrical signal in the first region is higher than a voltage of the first electrical signal in the second region. In some exemplary embodiments, the piezoelectric sensing component 440 may be disposed only in the first region. It should be noted that, the first region and the second region may be regions corresponding to the cavity 220, and may not include a region at a junction between the vibration component 420 and the base 200.

To improve the sensitivity of the vibration sensor 001, the vibration component 420 may include the counterweight 426. Because the counterweight 426 is in rigid connection with the elastic layer 424, deformation of the piezoelectric layer 441 corresponding to a position of the counterweight 426 is relatively small, and a voltage of a valid electrical signal is also relatively low. In addition, at a position close to the counterweight 426 or a position close to a junction between the elastic layer 424 and the base 200, deformation of the piezoelectric layer 441 is relatively large, and the voltage of the valid electrical signal is also relatively high. Therefore, the piezoelectric sensing component 440 may not be disposed at the position where the counterweight 426 is disposed. The first region may include at least one of a peripheral region close to the counterweight 426 and around the counterweight 426, and a region close to the junction between the elastic layer 424 and the base 200. The second region may include a region corresponding to the position where the counterweight 426 is disposed. The second region may substantially cover a surface area of the counterweight 426. In other words, an area of the second region may be equal to, or slightly smaller than, or slightly greater than the surface area of the counterweight 426. The piezoelectric sensing component 440 may be disposed in the first region. In other words, the piezoelectric sensing component 440 may be disposed in at least one of the peripheral region close to the counterweight 426 and around the counterweight 426, and the region close to the junction between the elastic layer 424 and the base 200. Specifically, the first piezoelectric electrode layer 442 and the second piezoelectric electrode layer 444 may be disposed in at least one of the peripheral region close to the counterweight 426 and around the counterweight 426, and the region close to the junction between the elastic layer 424 and the base 200.

The first piezoelectric electrode layer 442 may include at least one first piezoelectric electrode piece. The second piezoelectric electrode layer 444 may include at least one second piezoelectric electrode piece. Each of the at least one first piezoelectric electrode piece may be positionally aligned with at least one of the at least one second piezoelectric electrode piece. In some exemplary embodiments, each of the first piezoelectric electrode piece may positionally correspond to one second piezoelectric electrode piece. In some exemplary embodiments, each of the at least one first piezoelectric electrode piece may positionally correspond to a plurality of second piezoelectric electrode pieces, for example, 2, 3, 4, or another quantity of second piezoelectric electrode pieces. The plurality of second piezoelectric electrode pieces may connect in series with the first piezoelectric electrode piece as a common terminal to form output units connected in series, thereby increasing an output voltage, and improving sensitivity. The plurality of second piezoelectric electrode pieces may alternatively connect in parallel with the first piezoelectric electrode piece to form output units, thereby increasing an output charge, and improving sensitivity. An example in which the elastic layer 424 includes four elastic supporting beams 424-1 is used for description. Combinations of the first piezoelectric electrode piece and the second piezoelectric electrode piece in piezoelectric sensing components 440 between different elastic supporting beams may be different. The piezoelectric sensing component 440 may include only output units connected in series, only output units connected in parallel, or both output units connected in series and output units connected in parallel.

In some exemplary embodiments, the first piezoelectric electrode layer 442 and the second piezoelectric electrode layer 444 may alternatively be disposed on a same side of the piezoelectric layer 441 with an interval. For example, the first piezoelectric electrode layer 442 and the second piezoelectric electrode layer 444 may be disposed on a side of the piezoelectric layer 441 close to a vibration unit 420 with an interval, or a side of the piezoelectric layer 441 away from the vibration unit 420 with an interval. When the first piezoelectric electrode layer 442 and the second piezoelectric electrode layer 444 are disposed on a same side of the piezoelectric layer 441 with an interval, the first piezoelectric electrode piece may be bent to form a first comb-teethed structure; and the second piezoelectric electrode piece may be bent to form a second comb-teethed structure (not shown in FIG. 1 to FIG. 4). The first comb-teethed structure may include a plurality of comb-teethed structures. First spacing distances may exist between adjacent comb-teethed structures of the first comb-teethed structure. The first spacing distances may be the same or different. The second comb-teethed structure may include a plurality of comb-teethed structures. Second spacing distances may exist between adjacent comb-teethed structures of the second comb-teethed structure. The second spacing distances may be the same or different. The first comb-teethed structure may match the second comb-teethed structure to form the piezoelectric sensing component 440. Further, the comb-teethed structures of the first comb-teethed structure may extend into the second spacing distances of the second comb-teethed structure; the comb-teethed structures of the second comb-teethed structure may extend into the first spacing distances of the first comb-teethed structure, thereby matching with each other to form the piezoelectric sensing component 440. The first comb-teethed structure and the second comb-teethed structure may match with each other, so that the first piezoelectric electrode layer 442 and the second piezoelectric electrode layer 444 are arranged compactly with contacting each other. In some exemplary embodiments, the first comb-teethed structure and the second comb-teethed structure may extend in a length direction of the cantilever beam 424-3 (for example, a direction from the fixed end to the free end).

In some exemplary embodiments, the piezoelectric sensing component 440 may further include a first connection terminal 446, which is connected to the first piezoelectric electrode layer 442 or the second piezoelectric electrode layer 444 to output the first electrical signal to an external processing circuit.

The capacitive system 600 may be directly or indirectly fixedly connected with the base 200, and disposed opposite to the piezoelectric system 400 with an interval. The capacitive system 600 may include a fixed substrate 620 and a capacitive sensing component 640. The capacitive system 600 may use the vibration component 420 in the piezoelectric system 400 as a movable capacitive plate in the capacitive system 600. The capacitive system 600 may cause, based on the target displacement of the vibration component 420, a change in the distance between the vibration component 420 and the fixed substrate 620, thereby generating a voltage, and then converting the voltage to a second electrical signal.

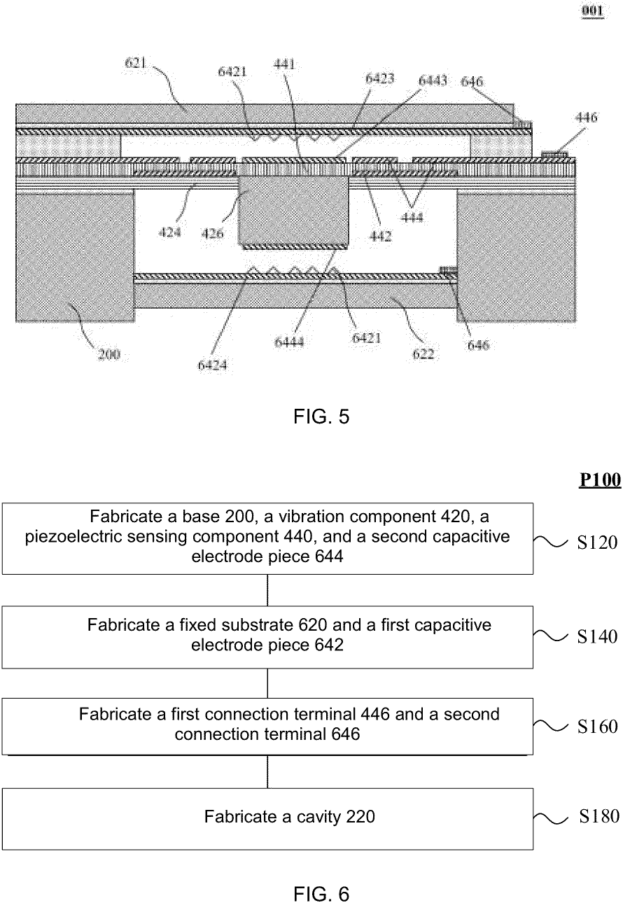

The fixed substrate 620 may be connected with the base 200 directly or indirectly. An example in which the piezoelectric system 400 is connected to the upper surface of the base 200 is used for description. The fixed substrate 620 may be disposed above the piezoelectric system 400 (as shown in FIG. 1 to FIG. 4), namely, a side of the piezoelectric system 400 away from the base 200; or may be disposed below the piezoelectric system 400, namely, a side of the piezoelectric system 4 close to the base 200 00; or may be disposed both above and below the piezoelectric system 400 (as shown in FIG. 5). The connection may be implemented in any manner, for example, a fixed connection manner such as welding, riveting, clamping, or bolting, or a deposition manner such as physical deposition (for example, physical vapor deposition) or chemical deposition (for example, chemical vapor deposition). The fixed substrate 620 may be connected to the base 200 in an insulated manner. For example, the fixed substrate 620 may be connected to the base 200 via a second insulation layer 202. The fixed substrate 620 may be a structural body of any shape, for example, a structural body of a regular shape or an irregular shape, where the regular shape may be a cube, a cuboid, a cylinder, a prismoid, a truncated cone, or the like.

The fixed substrate 620 may be disposed opposite to the vibration component 420 with an interval, to form a parallel-plate capacitor. The vibration component 420 may be used as a movable capacitive plate of the parallel-plate capacitor. When the vibration component 420 moves relative to the base 200 and the fixed substrate 620 based on an excitation of the vibration of the base 200, and generates the target deformation and the target displacement, the distance between the vibration component 420 and the fixed substrate 620 may change, thereby causing a change of capacitance value of the parallel-plate capacitor. In the case of a given bias voltage, the change of the capacitance value may be further converted into a change of an electrical signal, thereby implementing power-electricity conversion, and generating the second electrical signal.

A distance between the fixed substrate 620 and the vibration component 420 may be set in advance, or may be changed or adjusted. The distance between the fixed substrate 620 and the vibration component 420 may alternatively be set or changed based on a parameter of the vibration component 420.

The capacitive sensing component 640 may be connected to the fixed substrate 620 and the vibration component 420 and configured to generate the second electrical signal based on a distance change between the fixed substrate 620 and the vibration component 420 caused by the target displacement. As described above, a deformation degree of the vibration component 420 in the first region may be relatively high and a deformation degree of the vibration component 420 in the second region is relatively low. The piezoelectric sensing component 440 may be disposed only in the first region. To improve space utilization, a space volume of the vibration sensor 001 may be reduced as far as possible. The capacitive sensing component 640 may be disposed in the second region of the vibration component 420, that is, the capacitive sensing component 640 may be positionally aligned with the counterweight 426, and may cover a region corresponding to the counterweight 426. In other words, the capacitive sensing component 640 may be disposed right above or under the counterweight 426.

In the vibration sensor 001, the piezoelectric sensing component 440 and the capacitive sensing component 640 may be distributed in different regions in a space based on distribution characteristics of an electrical signal; the piezoelectric sensing component 440 may be distributed in a region having relatively high first electrical signal; and the capacitive sensing component 640 may be distributed in a region having relatively low first electrical signal and relatively high second electrical signal, thereby improving space utilization of the vibration sensor 001, reducing space waste, and improving sensitivity of the vibration sensor 001.

FIG. 1 and FIG. 2 are used as examples for description. The second region may include a region within a preset range near the center of the cavity 220. In other words, the second region may include a region corresponding to the position where the counterweight 426 is disposed. The second region may substantially cover a surface area of the counterweight 426. The first region may include at least one of a peripheral region close to the second region and around the second region, and a region close to the junction between the elastic layer 424 and the base 200. The piezoelectric sensing component 440 may be disposed in the first region. The capacitive sensing component 640 may be disposed in the second region. The piezoelectric sensing component 440 may be distributed in a peripheral direction around the capacitive sensing component 640. In addition, in a process when the vibration component 420 moves relative to the base 200, displacement at a position in a central region of the vibration component 420 may be relatively large, and displacement at the position where the counterweight 426 is disposed is also relatively large. Therefore, the second region may include the central region of the vibration component 420. The capacitive sensing component 640 may be distributed in the central region of the vibration component 420 or the region corresponding to the position where the counterweight 426 is disposed, so that a larger distance change may be obtained, thereby increasing an output voltage of the second electrical signal.

The capacitive sensing component 640 may include a first capacitive electrode piece 642 and a second capacitive electrode piece 644. The first capacitive electrode piece 642 and the second capacitive electrode piece 644 may be disposed opposite to each other. The first capacitive electrode piece 642 may be attached to a side of the fixed substrate 620 close to the vibration component 420. The first capacitive electrode piece 642 may be connected to the fixed substrate 620 in an insulated manner, that is, the first capacitive electrode piece 642 may be connected to the fixed substrate 620 via a third insulation layer 203. The second capacitive electrode piece 644 may be attached to a side of the vibration component 420 close to the fixed substrate 620. The second capacitive electrode piece 644 may be positionally aligned with the counterweight 426, and may cover a region corresponding to the counterweight 426. The piezoelectric sensing component 440 may be distributed in a peripheral direction around the second capacitive electrode piece 644. The first capacitive electrode piece 642 and the second capacitive electrode piece 644 may be consistent in pattern through patterned etching, thereby corresponding to each other.

In some exemplary embodiments, the first capacitive electrode piece 642 may include a position limit protector 6421, disposed on the first capacitive electrode piece 642 and protruding to a side close to the vibration component 420. The position limit protector 6421 may be disposed at any position on the first capacitive electrode piece 642. The position limit protector 6421 may perform a limit protection function. For a relatively great impact, the position limit protector 6421 may limit amplitude of the vibration component 420, thereby avoiding damage to a device (such as the elastic layer 424) caused by excessive vibration. In some exemplary embodiments, the position limit protector 6421 may be disposed at a position of the first capacitive electrode piece 642 opposite to the second capacitive electrode piece 644, thereby avoiding a short circuit caused by contact between the first capacitive electrode piece 642 and the second capacitive electrode piece 644, and preventing attachment and bonding between the first capacitive electrode piece 642 and the second capacitive electrode piece 644. In some exemplary embodiments, the position limit protector may be a rigid structure (for example, a limiting block), or a structure having certain elasticity (for example, an elastic soft cushion, a buffering cantilever beam, or a structure provided with both a buffering support arm and a limiting block). A material of the position limit protector 6421 may be a polyimide, parylene, or another polymer material.

In some exemplary embodiments, the first capacitive electrode piece 642 and the second capacitive electrode piece 644 may be structures of a conductive material. Exemplarily, the conductive material may include a metal, an alloy material, a metal oxide material, graphene, or the like, or any combination thereof. In some exemplary embodiments, the metal may include nickel, iron, lead, platinum, titanium, copper, molybdenum, zinc, or any combination thereof. In some exemplary embodiments, the alloy material may include a copper-zinc alloy, a copper-tin alloy, a copper-nickel-silicon alloy, a copper-chromium alloy, a copper-silver alloy, or any combination thereof. In some exemplary embodiments, the metal oxide material may include RuO₂, MnO₂, PbO₂, NiO, or the like, or any combination thereof.

In some exemplary embodiments, the capacitive sensing component 640 may further include a second connection terminal 646, connected to the second capacitive electrode piece 644, thereby outputting the second electrical signal to an external processing circuit.

As described above, in some exemplary embodiments, the fixed substrate 620 may be disposed both above and below the piezoelectric system 400. FIG. 5 is a sectional view of a vibration sensor 001 according to some exemplary embodiments of this disclosure. As shown in FIG. 5, the fixed substrate 620 may be disposed both above and below the piezoelectric system 400. As shown in FIG. 5, the fixed substrate 620 may include an upper fixed substrate 621 and a lower fixed substrate 622. The first capacitive electrode piece 642 may include a first upper capacitive electrode piece 6423 and a first lower capacitive electrode piece 6424. The second capacitive electrode piece 644 may include a second upper capacitive electrode piece 6443 and a second lower capacitive electrode piece 6444.

The upper fixed substrate 621 and the lower fixed substrate 622 may be fixedly connected to the base 200 respectively, and disposed on two sides of the vibration component 420 respectively. For example, the upper fixed substrate 621 may be disposed on a side of the vibration component 420 away from the counterweight 426, that is, the upper fixed substrate 621 may be disposed above the vibration component 420. The lower fixed substrate 622 may be disposed on a side of the vibration component 420 close to the counterweight 426, that is, the lower fixed substrate 622 may be disposed below the vibration component 420.

The first upper capacitive electrode piece 6423 may be attached to a side of the upper fixed substrate 621 close to the vibration component 420. The second upper capacitive electrode piece 6443 may be attached to a side of the vibration component 621 close to the upper fixed substrate 621, and disposed opposite to the first upper capacitive electrode piece 6423.

The first lower capacitive electrode piece 6424 may be attached to a side of the lower fixed substrate 622 close to the vibration component 420. The second lower capacitive electrode piece 6444 may be attached to a side of the vibration component 620 close to the lower fixed substrate 622, and disposed opposite to the first lower capacitive electrode piece 6421.

When the vibration component 420 generates the target displacement based on the vibration of the base 200, distances from the vibration component 420 to the upper fixed substrate 621 and the lower fixed substrate 622 are simultaneously changed. When the distance from the vibration component 420 to the upper fixed substrate 621 is decreased, the distance from the vibration component 420 to the lower fixed substrate 622 is increased. When the distance from the vibration component 420 to the upper fixed substrate 621 is increased, the distance from the vibration component 420 to the lower fixed substrate 622 is decreased. The first upper capacitive electrode piece 6423 and the second upper capacitive electrode piece 6443 collect an upper second electrical signal generated when the distance from the vibration component 420 to the upper fixed substrate 621 changes. The first lower capacitive electrode piece 6421 and the second lower capacitive electrode piece 6444 collect a lower second electrical signal generated when the distance from the vibration component 420 to the lower fixed substrate 622 changes. The second electrical signal may include the upper second electrical signal and the lower second electrical signal.

The first upper capacitive electrode piece 6423 may include a position limit protector 6421, disposed on the first upper capacitive electrode piece 6423 and protruding toward a side thereof close to the vibration component 420. The first lower capacitive electrode piece 6424 may also include a position limit protector 6421, disposed on the first lower capacitive electrode piece 6424 and protruding toward a side thereof close to the vibration component 420.

The second connection terminal 646 may output the upper second electrical signal and the lower second electrical signal to an external processing circuit for synthesis through a differential algorithm, thereby increasing the second electrical signal output by the capacitive system 600, and further improving sensitivity of the vibration sensor 001.

This disclosure further provides a microphone. The microphone may include a housing and the vibration sensor 001 provided in this disclosure. The vibration sensor 001 may be mounted in the housing. The housing may be fixedly connected to the base 200. The housing and the base 200 may be integrated, or may be formed separately and fixedly connected in a manner such as welding, riveting, bolting, or bonding. When the housing vibrates driven by an external force (for example, when a person speaks, facial vibration drives the housing to vibrate), the vibration of the housing drives the base 200 to vibrate. Because the vibration component 420 and the housing structure (or the base 200) have different characteristics, movement of the vibration component 420 and movement of the housing structure (or the base 200) are not identical, thereby generating relative movement, and further causing the vibration component 420 to generate the target deformation and the target displacement. The piezoelectric sensing component 440 and the capacitive sensing component 640 convert the target deformation and the target displacement to the first electrical signal and the second electrical signal.

In some exemplary embodiments, the microphone may further include a signal synthesizing circuit. The signal synthesizing circuit may be connected to the piezoelectric sensing component 440 and the capacitive sensing component 640, and configured to synthesize a third electrical signal based on the first electrical signal and the second electrical signal during operation. A signal strength of the third electrical signal is greater than both a signal strength of the first electrical signal and a signal strength of the second electrical signal. In some exemplary embodiments, the signal synthesizing circuit may be further configured to synthesize the second electrical signal based on the upper second electrical signal and the lower second electrical signal. A strength of the second electrical signal is greater than a strength of the upper second electrical signal and a strength of the upper second electrical signal.

The above is merely an example description. The microphone described in this disclosure may be applied to various electronic products, such as earphones (for example, bone-conduction earphones or air-conduction earphones, wireless earphones, or wired earphones), smart glasses, smart wearable devices, smart helmets, smart watches, or other devices with a voice collection function.

Thus, the vibration sensor 001 and the microphone 002 provided in this disclosure are composed of the piezoelectric system 400 and the capacitive system 600. The vibration component 420 in the piezoelectric system 400 may generate deformation by an external vibrational excitation, and move up and down relative to the base 200. The piezoelectric sensing component 440 may collect the first electrical signal generated based on the target deformation. The capacitive system 600 may use the vibration component 420 as the movable capacitive plate in the capacitive system 600. When the vibration component 420 moves up and down relative to the base 200, the distance between the vibration component 420 and the fixed substrate 620 may change correspondingly, and capacitance may also change correspondingly. The corresponding first capacitive electrode piece 642 and the second capacitive electrode piece 644 may be respectively disposed on the vibration component 420 and the fixed substrate 620 in the capacitive system 600, to collect the second electrical signal in the capacitive system 600, and obtain a voltage output from the second electrical signal. The vibration sensor 001 may output the first electrical signal and the second electrical signal to the external processing circuit. The external processing circuit may process the first electrical signal and the second electrical signal, so that the first electrical signal and the second electrical signal are combined, thereby improving the voltage of an output electrical signal of the vibration sensor 001, and improving sensitivity of the vibration sensor 001. In addition, internal space of the vibration sensor 001 is rationally utilized by distributing the piezoelectric sensing component 440 at a position where an output voltage of the first electrical signal is relatively high and distributing the capacitive sensing component 640 at a position where an output voltage of the second electrical signal is relatively high. Therefore, sensitivity of the vibration sensor 001 is improved while space waste is avoided.

Connection relationships between the base 200, the piezoelectric system 400, and the capacitive system 600 in the vibration sensor 001 may be implemented in a mechanical fixed connection manner such as welding, riveting, clamping, or bolting, or may be implemented in a deposition manner such as physical deposition (for example, physical vapor deposition) or chemical deposition (for example, chemical vapor deposition).

FIG. 6 is a flowchart of a method P100 for manufacturing a vibration sensor 001 according to some exemplary embodiments of this disclosure. In the method P100, the vibration sensor 001 is manufactured in a deposition manner. The vibration sensor 001 shown in FIG. 1 and FIG. 2 is used as an example. As shown in FIG. 6, the method P100 may include the following steps.

S120: Fabricate a base 200, a vibration component 420, a piezoelectric sensing component 440, and a second capacitive electrode piece 644.

Specifically, in step S120, etching may be performed on an integrated structure of the vibration component 420 and the base 200 formed by a Si substrate. Step S120 may include: sequentially depositing and etching a second capacitive electrode piece 644, a first piezoelectric electrode layer 442, a piezoelectric layer 224, and a second piezoelectric electrode layer 444 on an upper surface of an SOI silicon wafer and performing etching; performing corresponding patterned etching after each time of deposition, so as to obtain an electrode and lead pattern meeting a design; an elastic layer 424 is etched to reach a first insulation layer 201; a SiO₂ insulation layer material is deposited on a surface of the elastic layer 424; and then patterned etching and polishing are performed to obtain a second insulation layer 202.

In some exemplary embodiments, the vibration component 420 may further include a seed layer (not shown in FIG. 1 and FIG. 2), configured to provide another layer with a favorable growth surface structural body. The seed layer may be disposed on a surface of a piezoelectric layer 441. In some exemplary embodiments, a material of the seed layer may be the same as that of the piezoelectric layer 441. For example, when the material of the piezoelectric layer 441 is AIN, the material of the seed layer is also AIN. In some other embodiments, the material of the seed layer may alternatively be different from that of the piezoelectric layer 441.

S140: Fabricate a fixed substrate 620 and a first capacitive electrode piece 642.

Specifically, step S140 may include: sequentially depositing a SiO₂ layer (a third insulation layer 203) and a poly-crystalline silicon layer on a Si substrate; performing patterned etching on the poly-crystalline silicon layer to obtain the first capacitive electrode piece 642; depositing and etching a polymer material on a surface of the poly-crystalline silicon layer to obtain a position limit protector 6421; and combining the fixed substrate 620 with the third insulation layer 203, for example, through wafer bonding.

S160: Fabricate a first connection terminal 446 and a second connection terminal 646.

Specifically, step S160 may include: performing patterned through-hole etching on the fixed substrate 620, to obtain mounting positions of the first connection terminal 446 and the second connection terminal 646; and fabricating the first connection terminal 446 and the second connection terminal 646.

S180: Fabricate a cavity 220.

Specifically, step S180 may include: performing patterned etching on the Si substrate of the base 200 to obtain the cavity 220 and a counterweight 426; and performing etching on SiO₂ in the first insulation layer 201 to release the elastic layer 424, so as to obtain a free end of the elastic layer 424.

The above describes specific embodiments of this disclosure. Other embodiments are within the scope of the appended claims. In some cases, the actions or steps described in the claims may be performed in an order different from that described in the embodiments and a desired result can still be achieved. In addition, the processes described in the accompanying drawings may still achieve a desired result without a specific order or a continuous order as shown. In some implementations, multiple-task processing and parallel processing may also be possible or may be advantageous.

Thus, after reading this detailed disclosure, those skilled in the art can understand that the foregoing detailed disclosure may be presented exemplarily, and may not be restrictive. Although it is not explicitly stated herein, those skilled in the art can understand that this disclosure covers various reasonable changes, improvements, and modifications of the embodiments. These changes, improvements, and modifications are intended to be included in this disclosure, and are within the spirit and scope of the exemplary embodiments of this disclosure.

In addition, some terms in this disclosure have been used to describe the embodiments of this disclosure. For example, “one embodiment”, “an embodiment”, and/or “some exemplary embodiments” mean that specific features, structures, or characteristics described in combination with the embodiments may be included in at least one embodiment of this disclosure. Therefore, it may be emphasized and should be understood that two or more references to “an embodiment”, “one embodiment”, or “an alternative embodiment” in various parts of this disclosure do not necessarily refer to the same embodiment. In addition, specific features, structures, or characteristics may be appropriately combined in one or more embodiments of this disclosure.

It should be understood that in the foregoing description of the embodiments of this disclosure, to facilitate understanding a feature, for the purpose of simplifying this disclosure, various features may be combined in a single embodiment, an accompanying drawing, or the description thereof in this disclosure. However, this does not indicate that the combination of these features is necessary. It is possible for those skilled in the art to extract some of these features as a separate embodiment for understanding when reading this disclosure. In other words, the embodiments in this disclosure may also be understood as an integration of a plurality of secondary embodiments. The same rule may be applied to the cases where the content of each secondary embodiment contains features less than all the features of a separate embodiment disclosed above.

Each patent, patent application, publication of a patent application, and other materials, such as articles, books, publications, documents, articles, etc., cited herein, except for any historical prosecution documents to which it relates, which may be inconsistent with or any identities that conflict, or any identities that may have a restrictive effect on the broadest scope of the claims, are hereby incorporated by reference for all purposes now or hereafter associated with this document. Furthermore, in the event of any inconsistency or conflict between the description, definition, and/or use of a term associated with any contained material, the term used in this document shall prevail.

Finally, it should be understood that some exemplary embodiments are illustrated to schematically describe the implementation of this disclosure. Other embodiments may also fall within the scope of this disclosure. Therefore, the embodiments disclosed in this disclosure are only exemplary but not restrictive. Those skilled in the art may implement the present disclosure with an alternative configuration of the embodiments provided in this disclosure. Therefore, the embodiments of this disclosure are not limited to the exemplary embodiments explicitly described herein.

What is claimed is:

1. A vibration sensor, comprising:
a base;
a vibration component, connected to the base and configured to generate a target displacement and a target deformation in response to a vibration of the base;
a piezoelectric sensing component, connected to the vibration component and configured to convert the target deformation to a first electrical signal;
a fixed substrate, disposed opposite to the vibration component with an interval; and
a capacitive sensing component, connected to the fixed substrate and the vibration component, and configured to convert a distance change between the fixed substrate and the vibration component caused by the target displacement to a second electrical signal.

2. The vibration sensor according to claim 1, wherein the vibration component includes:
an elastic layer, connected to the base and configured to generate the target deformation in response to an excitation of the vibration of the base; and
a counterweight, connected to the elastic layer and configured to generate the target displacement based on the target deformation.

3. The vibration sensor according to claim 2, wherein the base includes a cavity penetrating the base, and at least a part of the vibration component is suspended in the cavity.

4. The vibration sensor according to claim 3, wherein the elastic layer includes:
a fixed end, fixedly connected to the base; and
a free end, suspended in the cavity, wherein
the counterweight is fixedly connected to the free end of the elastic layer, and suspended in the cavity.

5. The vibration sensor according to claim 4, wherein the elastic layer includes:
a plurality of elastic supporting beams, wherein
one end of each elastic supporting beam is fixedly connected to the base, and
another end of each elastic supporting beam is connected to the counterweight and suspended in the cavity.

6. The vibration sensor according to claim 4, wherein the elastic layer includes:
a suspended membrane structure, wherein
a periphery of the suspended membrane structure is fixedly connected to the base, and
a central region of the suspended membrane structure is connected to the counterweight and suspended in the cavity.

7. The vibration sensor according to claim 2, wherein a position of the capacitive sensing component is aligned with a position of the counterweight, and covers a region corresponding to the counterweight.

8. The vibration sensor according to claim 7, wherein the capacitive sensing component includes:
a first capacitive electrode piece, attached to a side of the fixed substrate close to the vibration component; and
a second capacitive electrode piece, attached to a side of the vibration component close to the fixed substrate and disposed opposite to the first capacitive electrode piece.

9. The vibration sensor according to claim 8, wherein a position of the second capacitive electrode piece is aligned with a position of the counterweight, and covers a region corresponding to the counterweight.

10. The vibration sensor according to claim 8, wherein the first capacitive electrode piece includes:
a position limit protector, disposed on the first capacitive electrode piece and protruding towards a side close to the vibration component, wherein
the position limit protector limits the target displacement of the vibration component to prevent the second capacitive electrode piece from contacting with the first capacitive electrode piece.

11. The vibration sensor according to claim 8, wherein
the fixed substrate includes an upper fixed substrate disposed on a side of the vibration component away from the counterweight;
the first capacitive electrode piece includes a first upper capacitive electrode piece attached to a side of the upper fixed substrate close to the vibration component; and
the second capacitive electrode piece includes a second upper capacitive electrode piece attached to a side of the vibration component close to the upper fixed substrate and disposed opposite to the first upper capacitive electrode piece.

12. The vibration sensor according to claim 8, wherein
the fixed substrate further includes a lower fixed substrate disposed on a side of the vibration component close to the counterweight;
the first capacitive electrode piece further includes a first lower capacitive electrode piece attached to a side of the lower fixed substrate close to the vibration component; and
the second capacitive electrode piece further includes a second lower capacitive electrode piece attached to a side of the vibration component close to the lower fixed substrate and disposed opposite to the first lower capacitive electrode piece.

13. The vibration sensor according to claim 7, wherein
the piezoelectric sensing component is disposed in at least one of the following regions:
a peripheral region close to and surrounding the counterweight; or
a region close to a junction between the elastic layer and the base.

14. The vibration sensor according to claim 13, wherein the piezoelectric sensing component includes:
a piezoelectric layer, fixedly connected to the base and attached to a surface of the elastic layer, wherein
the piezoelectric layer is configured to generate a voltage based on the target deformation.

15. The vibration sensor according to claim 14, wherein the piezoelectric sensing component further includes:
a first piezoelectric electrode layer and a second piezoelectric electrode layer, respectively disposed on surfaces of two sides of the piezoelectric layer and configured to convert the voltage to the first electrical signal, wherein
the first piezoelectric electrode layer and the second piezoelectric electrode layer are positionally aligned with each other, and disposed in at least one of the following regions:
the peripheral region close to and surrounding the counterweight, or
the region close to the junction between the elastic layer and the base.

16. The vibration sensor according to claim 15, wherein
the first piezoelectric electrode layer includes at least one first piezoelectric electrode piece;
the second piezoelectric electrode layer includes at least one second piezoelectric electrode piece; and
each of the at least one first piezoelectric electrode piece is positionally aligned with one or more of the at least one second piezoelectric electrode piece.

17. A microphone, comprising:
a housing;
a vibration sensor mounted in the housing, wherein the vibration sensor includes:
a base,
a vibration component, connected to the base and configured to generate a target displacement and a target deformation in response to a vibration of the base,
a piezoelectric sensing component, connected to the vibration component and configured to convert the target deformation to a first electrical signal,
a fixed substrate, disposed opposite to the vibration component with an interval, and
a capacitive sensing component, connected to the fixed substrate and the vibration component, and configured to convert a distance change between the fixed substrate and the vibration component caused by the target displacement to a second electrical signal, wherein
the base is fixedly connected to the housing; and
a signal synthesizing circuit, connected to the piezoelectric sensing component and the capacitive sensing component, and configured to synthesize a third electrical signal based on the first electrical signal and the second electrical signal, wherein
a signal strength of the third electrical signal is greater than a signal strength of the first electrical signal and a signal strength of the second electrical signal.

18. The microphone according to claim 17, wherein the vibration component includes:
an elastic layer, connected to the base and configured to generate the target deformation in response to an excitation of the vibration of the base; and
a counterweight, connected to the elastic layer and configured to generate the target displacement based on the target deformation.

19. The microphone according to claim 18, wherein the base includes a cavity penetrating the base, and at least a part of the vibration component is suspended in the cavity.

20. The microphone according to claim 19, wherein the elastic layer includes:
a fixed end, fixedly connected to the base; and
a free end, suspended in the cavity, wherein
the counterweight is fixedly connected to the free end of the elastic layer, and suspended in the cavity.
